(19) United States
(12) Patent Application Publication
(10) Pub. No.: US 2012/0019988 A1
(43) Pub. Date: Jan. 26, 2012

(54) SHELL AND ELECTRONIC DEVICE USING THE SAME

(75) Inventors: JI-FENG QIU, Shenzhen City (CN); YONG-MIN LI, Shenzhen City (CN); LI-NI LIANG, Shenzhen City (CN)

(73) Assignees: HON HAI PRECISION INDUSTRY CO., LTD., Tu-Cheng,Taipei Hsien (TW); HONG FU JIN PRECISION INDUSTRY (ShenZhen) CO., LTD., Shenzhen City (CN)

(21) Appl. No.: 12/906,900

(22) Filed: Oct. 18, 2010

(30) Foreign Application Priority Data
Jul. 22, 2010 (CN) 201010233914.4

(51) Int. Cl. H05K 7/00

(52) U.S. Cl. 361/679.01

(57) ABSTRACT

A shell of an electronic device for fixing a display panel is provided. The shell includes a main body and at least two securing member fixed on the main body. The main body defines a receiving space for receiving the display panel. At least one restricting member protrudes integrally from the main body. An end of the at least one restricting member extends toward the receiving space and cooperates with a bottom of the receiving space to define an intervening space. The intervening space is used for holding an end of the display panel, and at least two securing members are fixed to the main body to retain the opposite end of the display panel, whereby the display panel is fixed to the shell. An electronic device using the shell is also provided.

### BACKGROUND

1. Technical Field

The present disclosure relates to a shell of an electronic device.

2. Description of Related Art

A display panel, such as a liquid crystal display (LCD) panel, is generally mounted to a shell of a display device by a plurality of fixing members, such as screws, however fixing the screws to the shell can be time consuming

Therefore, there is room for improvement in the art.

### BRIEF DESCRIPTION OF THE DRAWINGS

The components of the drawings are not necessarily drawn to scale, the emphasis instead being placed upon clearly illustrating the principles of the embodiments of the shell of a display device. Moreover, in the drawings, like reference numerals designate corresponding parts throughout several views.

FIG. 1 is a perspective view of a display device in accordance with one embodiment.

FIG. 2 is a disassembled view of the display device in FIG. 1; the display device includes a front portion having two securing members, a rear portion, and a display panel.

FIG. 3 is a partially assembled view of the display device in FIG. 2 showing one of the securing members fixed to the front portion.

FIG. 4 is a partially assembled view of the display device in FIG. 2 showing the display panel mounted to the front portion using the securing members.

### DETAILED DESCRIPTION

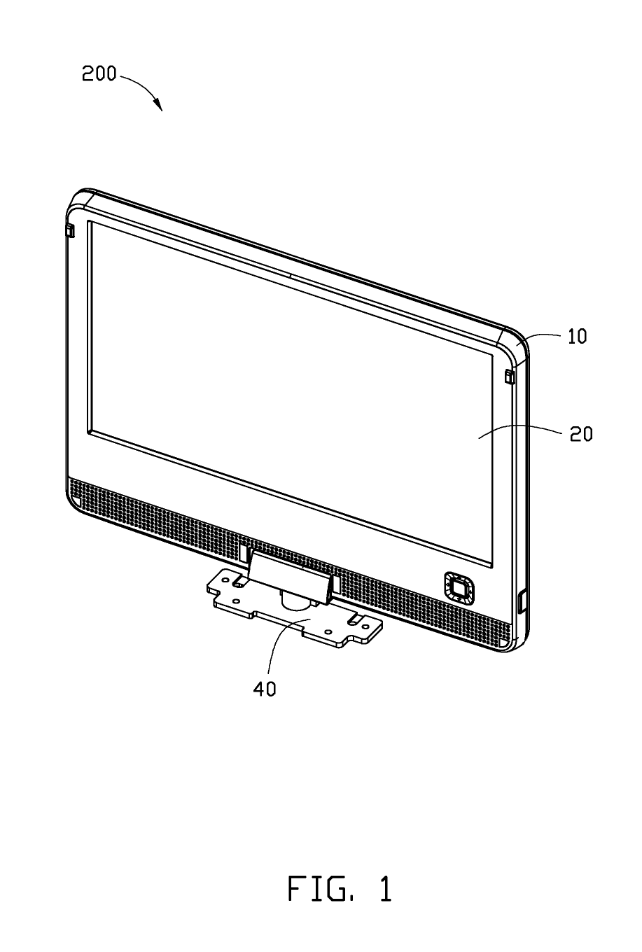

Referring to FIG. 1, a display device 200 is shown. The display device 200 can be an LCD of a computer or a TV. The display device 200 includes a shell 10, a display panel 20 received in the shell 10, and a circuit board (not shown) received in the shell 10. The shell 10 can be made of plastic material, or can be made of metal. The display device 200 further includes a stand 40.

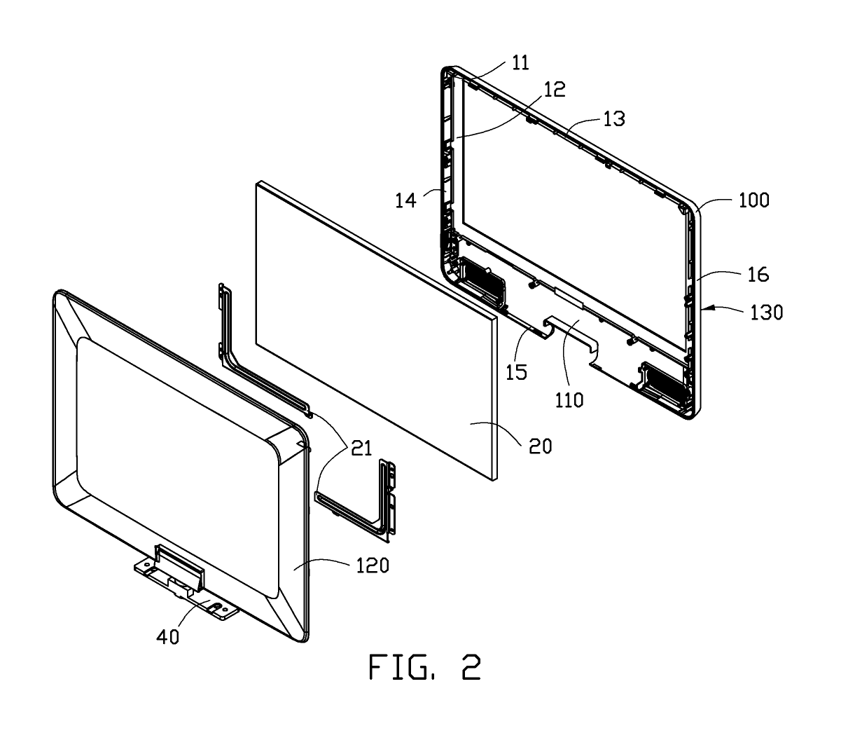

Referring also to FIG. 2, the shell 10 includes a front portion 100 and a rear portion 120. The front portion 100 covers on the rear portion 120 to form a receiving space (not labeled). The receiving space is used to receive the display panel 20 and the circuit board.

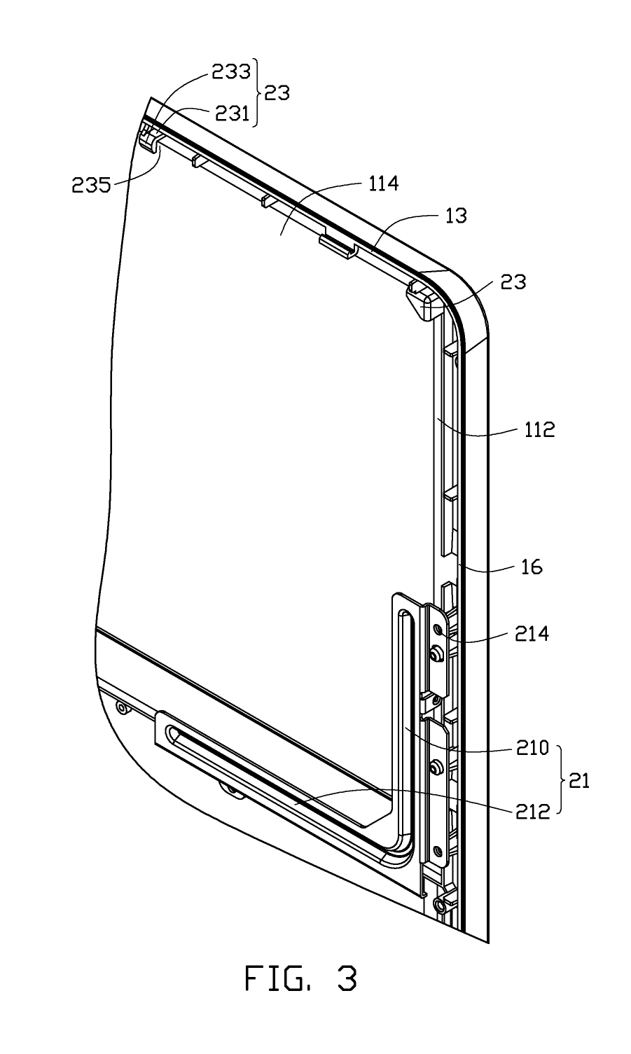

Referring further to FIG. 3, the display panel 20 is fixed to the front portion 100. The front portion 100 includes a main body 11 and two securing members 21 fixed to the main body 11.

The main body 11 includes a rectangular base 12, and four sidewalls (hereinafter, a first sidewall 13, a second sidewall 14, a third sidewall 15, and a fourth sidewall 16) protruding from four rims of the base 12. The first sidewall 13, the second sidewall 14, the third sidewall 15 opposite to the first sidewall 13, and the fourth sidewall 16 opposite to the second sidewall 14 are serially interconnected with each other to define a portion of the receiving space.

The base 12 includes an inner surface 110 facing the rear portion 120 and an outer surface 130 opposite to the inner surface 110. The inner surface 110 is recessed to define a receiving space 112. The receiving space 112 is substantially rectangular, and is used to receive the display panel 20. The receiving space 112 further defines an opening 114. The opening 114 is substantially rectangular, and the display panel 20 is visible through the opening 114. It is noteworthy that the size of the display panel 20 is slightly less than that of the receiving space 112 but is slightly larger than that of the opening 114.

A plurality of restricting members 23 protrude integrally from the main body 11. The plurality of restricting members 23 cooperates with the securing members 21 to hold the display panel 20 in the receiving space 112.

Each restricting member 23 includes a limiting portion 231 and a hook portion 233. The limiting portion 231 protrudes perpendicularly from the inner surface 110 of the base 11. The limiting portion 231 resists against one sidewall of the receiving space 112 adjacent to the first sidewall 13. The hook portion 233 protrudes from an end of the limiting portion 231 away from the inner surface 110, and extends toward the receiving space 112, thus, an intervening space 235 is formed between the hook portion 233 and the bottom of the receiving space 112. The intervening space 235 is used to accommodate an end of the display panel 20. The width of the intervening space 235 is slightly larger than the thickness of the display panel 20, such that the display panel 20 can be firmly held in place.

The securing members 21 are substantially L-shaped. The securing members 21 are fixed to the main body 11 and cooperate with the restricting members 23 to hold the display panel 20 in the receiving space 112. Each securing member 21 includes a first arm 210 and a second arm 212. The first arm 210 is perpendicular to the second arm 212. The two securing member 21 are fixed to two corners of the receiving space 112 adjacent to the third sidewall 15 respectively, with the two first arms 210 fixed respectively to opposite sidewalls of the receiving space 112 perpendicular to the third sidewall 15, and with the two second arms 212 fixed to opposite ends of a sidewall of the receiving space 112 adjacent to the third sidewall 15. The securing members 21 respectively define a plurality of holes 214. Fixing members, such as screws (not shown), extend through the corresponding holes 214 to fix the securing members 21 to the front portion 100.

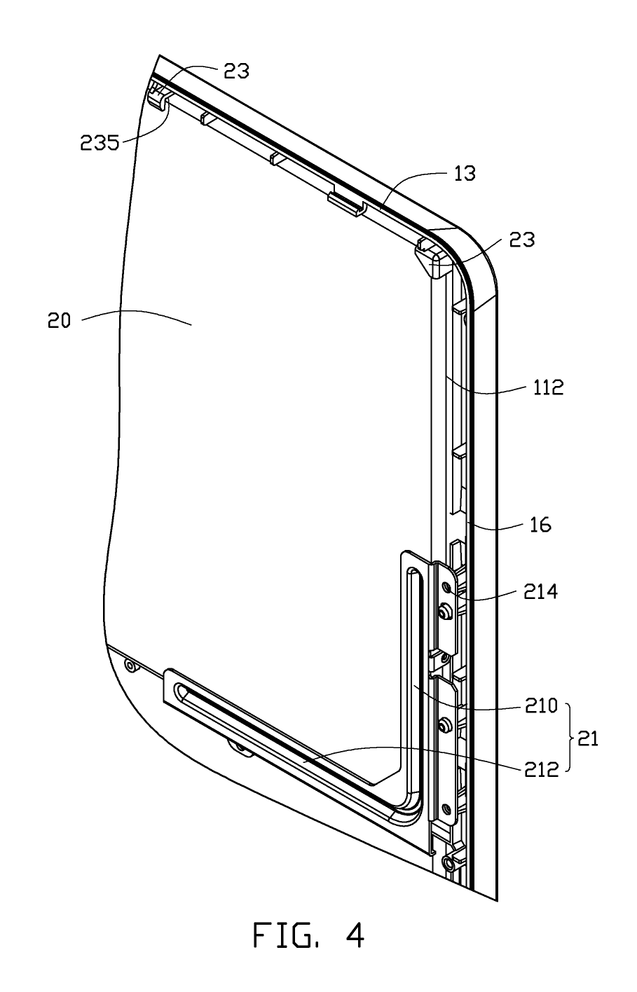

Referring further to FIG. 4, in assembly, firstly, the display panel 20 is accommodated in the receiving space 112 with an edges of the display panel 20 received in the intervening spaces 235. Secondly, the securing members 21 are fixed to main body 11. As a result, the display panel 20 is secured to the front portion 100 by the securing members 21 cooperating with the restricting members 23. Finally, after circuit boards and other electronic components are mounted to the rear potion 120, the front portion 100 is placed to cover the rear portion 120.

By virtue of the plurality of restricting members 23 protruding integrally from the front portion 100, the display panel 20 can be fixed to the shell 10 with fewer screws. As a result, it takes a less time to assemble the display panel 20 to the shell 10 of the display device 200.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A shell for accommodating a display panel, the shell comprising:
a main body defining a receiving space for receiving the display panel; and
at least two securing member fixed on the main body;
wherein at least one restricting member protrudes integrally from the main body, an end of the at least one restricting member extends toward the receiving space and cooperates with a bottom of the receiving space to define an intervening space, the intervening space is used for holding an end of the display panel, and the at least two securing members are fixed to the main body to retain the opposite end of the display panel, whereby the display panel is fixed to the shell.

2. The shell of claim 1, wherein the width of the intervening space is slightly larger than the thickness of the display panel.

3. The shell of claim 2, wherein each restricting member comprises a limiting portion and a hook portion, the limiting portion protrudes from the main body and resist against a sidewall of the receiving space, the hook portion protrudes from an free end of the limiting portion and extends toward the receiving space, and the intervening space is formed between the hook portion and the bottom of the receiving space.

4. The shell of claim 1, wherein the bottom of the receiving space further defines an opening and the display panel is visible through the opening.

5. The shell of claim 1, wherein the at least two securing members are fixed to the main body and are opposite to the at least one restricting member.

6. An electronic device, comprising:
a display panel; and
a shell for receiving the display panel, comprising:
a rear portion; and
a front portion covering on the rear portion, wherein the front portion comprises a main body and at least two securing member fixed to the main body, at least one restricting member protrudes integrally from the main body, an end of the at least one restricting member extends toward the receiving space and cooperates with a bottom of the receiving space to define an intervening space, the intervening space is used for holding an end of the display panel, and the at least two securing members are fixed to the main body to retain the opposite end of the display panel, whereby the display panel is fixed to the shell.

7. The electronic device of claim 6, wherein the width of the intervening space is slightly larger than the thickness of the display panel.

8. The electronic device of claim 7, wherein each restricting member comprises a limiting portion and a hook portion, the limiting portion protrudes from the main body and resist against a sidewall of the receiving space, the hook portion protrudes from an free end of the limiting portion and extends toward the receiving space, and the intervening space is formed between the hook portion and the bottom of the receiving space.

9. The electronic device of claim 6, wherein bottom of the receiving space further defines an opening and the display panel is visible through the opening.

10. The electronic device of claim 6, wherein the at least two securing members are fixed to the main body and are opposite to the at least one restricting member.
